(19) United States
(12) Patent Application Publication
(10) Pub. No.: US 2016/0300950 A1
(43) Pub. Date: Oct. 13, 2016

(54) THIN FILM TRANSISTOR ARRAY PANEL AND METHOD FOR MANUFACTURING THE SAME

(71) Applicant: Samsung Display Co., Ltd., Yongin-si (KR)

(72) Inventors: Hyeon Jun LEE, Hwaseong-si (KR); Ki Won Kim, Suwon-si (KR); Yoo Ho Kim, Asan-si (KR); Joon Geol Kim, Hwaseong-si (KR); Doo Hyoung Lee, Suwon-si (KR)

(21) Appl. No.: 14/887,483

(22) Filed: Oct. 20, 2015

(30) Foreign Application Priority Data
Apr. 7, 2015 (KR) 10-2015-0049113

(51) Int. Cl. H01L 29/786; H01L 29/423; H01L 29/45; H01L 21/4763; H01L 29/22; H01L 29/66; H01L 21/44; H01L 27/12; H01L 29/24

(52) U.S. Cl. CPC H01L 29/7869; H01L 27/124; H01L 29/42384; H01L 29/45; H01L 29/24; H01L 29/22; H01L 29/66969; H01L 27/1259; H01L 27/1225; H01L 21/44; H01L 21/47635

(57) ABSTRACT

A thin film transistor array panel includes a gate line disposed on a substrate, the gate line including a gate electrode, a gate insulating layer disposed on the gate electrode, a semiconductor layer disposed on the substrate, the semiconductor layer including an oxide semiconductor, a data line disposed on the substrate and crossing the gate line, a data line layer including a source electrode connected to the data line and a drain electrode facing the source electrode, and a passivation layer covering the source electrode and the drain electrode. The data line layer includes copper or a copper alloy, and the semiconductor layer includes a copper doped oxide semiconductor. A content of copper doped on the oxide semiconductor is 0.2% to 0.82%.

### CROSS-REFERENCE TO RELATED APPLICATION

This application claims priority from and the benefit of Korean Patent Application No. 10-2015-0049113, filed on Apr. 7, 2015, which is hereby incorporated by reference for all purposes as if fully set forth herein.

### BACKGROUND

1. Field

Exemplary embodiments relate to a thin film transistor array panel and a method for manufacturing the same.

2. Discussion of the Background

Various display devices such as a liquid crystal display (LCD) device, an organic light emitting diode (OLED) display device, a plasma display device, an electrophoretic display device, and an electrowetting display device may be used.

The liquid crystal display device is one display device that is widely used and includes two display panels having field generating electrodes such as a pixel electrode and a common electrode, a liquid crystal layer interposed the field generating electrodes, and a backlight unit providing light to the display panels holding the liquid crystal layer. In the liquid crystal display device, images are displayed by applying a voltage to the field generating electrode to form an electric field on the liquid crystal layer, determining directions of liquid crystal molecules of the liquid crystal layer through the electric field, and controlling an emission amount of light provided by the backlight unit.

In general, the display device including the liquid crystal display device includes a thin film transistor array panel. The thin film transistor array panel is composed of a gate electrode that is a part of a gate line, a semiconductor layer forming a channel, and a source electrode and a drain electrode that are parts of a data line. The thin film transistor is a switching element transferring image signals transferred through a data line to a pixel electrode or blocking the image signals according to scanning signals transferred through a gate line.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide a thin film transistor array panel having advantages of increasing a lifetime of an element and improving reliability, and a method for manufacturing the same.

Additional aspects will be set forth in the detailed description which follows, and, in part, will be apparent from the disclosure, or may be learned by practice of the inventive concept.

An exemplary embodiment discloses a thin film transistor array panel includes a gate line disposed on a substrate, the gate line including a gate electrode, a gate insulating layer disposed on the gate electrode, a semiconductor layer disposed on the substrate, the semiconductor layer including an oxide semiconductor, a data line disposed on the substrate and crossing the gate line, a data line layer including a source electrode connected to the data line and a drain electrode facing the source electrode, and a passivation layer covering the source electrode and the drain electrode. The data line layer includes copper or a copper alloy, and the semiconductor layer includes a copper doped oxide semiconductor. A content of copper doped on the oxide semiconductor is 0.2% to 0.82%.

An exemplary embodiment also discloses a method for manufacturing a thin film transistor array panel. The method includes disposing a gate line including a gate electrode on a substrate, disposing a gate insulating layer on the gate line, disposing a semiconductor layer including an oxide semiconductor on the gate insulating layer, disposing a data line layer including a source electrode and a drain electrode on the semiconductor layer, treating surfaces of the source electrode and the drain electrode to diffuse copper to the semiconductor layer with heat and plasma, and disposing a passivation layer on the substrate to cover the source electrode, the drain electrode, and the semiconductor layer. The data line layer includes copper or a copper alloy, and the semiconductor layer includes a copper doped oxide semiconductor. A content of copper doped on the oxide semiconductor is 0.2% to 0.82%.

An exemplary embodiment further discloses a method for manufacturing a thin film transistor array panel. The thin film transitor array panel includes disposing a gate line including a gate electrode on a substrate, disposing a gate insulating layer on the gate line, disposing a semiconductor layer including an oxide semiconductor on the gate insulating layer, disposing an etch stopper on the semiconductor layer, disposing a data line layer including a source electrode and a drain electrode on the semiconductor layer so that a portion of the etch stopper is exposed, heat treating surfaces of the source electrode and the drain electrode to diffuse copper to the semiconductor layer, and disposing a passivation layer on the substrate to cover the source electrode, the drain electrode, and the etch stopper. The data line layer includes copper or a copper alloy, and the semiconductor layer includes a copper doped oxide semiconductor. A content of copper doped on the oxide semiconductor is 0.2% to 0.82%.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a plan view of a thin film transistor array panel according to an exemplary embodiment.

FIG. 2 is a cross-sectional view of the thin film transistor array panel taken along section line II-II′ in FIG. 1.

FIG. 3 is a cross-sectional view of a thin film transistor array panel according to an exemplary embodiment.

FIG. 4 is a graph illustrating negative bias under thermal and illumination stress (NBTIS) characteristics and leakage current (off current) values depending on a copper content in a semiconductor layer of a thin film transistor according to an exemplary embodiment.

FIG. 5 is a cross-sectional view of a thin film transistor array panel according to another exemplary embodiment.

FIGS. 6, 7, 8, 9, and 10 are views illustrating a manufacturing process of the thin film transistor array panel according to an exemplary embodiment.

FIG. 11 is a graph illustrating NBTIS shift values depending on a copper content in the semiconductor layer of the thin film transistor according to an exemplary embodiment.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

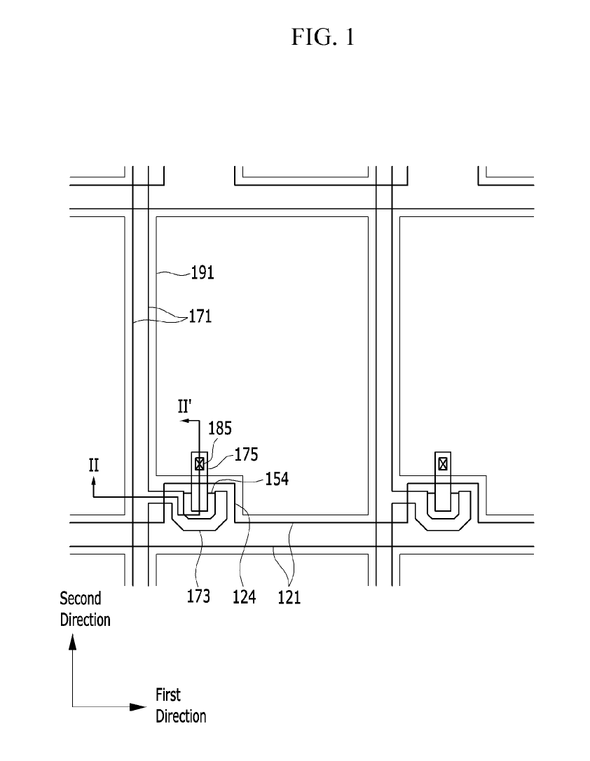

Hereinafter, a thin film transistor array panel according to an exemplary embodiment will be described in detail with reference to the accompanying drawings. FIG. 1 is a plan view of a thin film transistor array panel according to an exemplary embodiment. FIG. 2 is a cross-sectional view taken along line section line II-IF in FIG. 1.

First, the thin film transistor array panel according to an exemplary embodiment will be described with reference to FIGS. 1 and 2.

Gate lines 121 may extend in a first direction and data lines 171 may extend in a second direction crossing the first direction. The gate lines 121 and the data lines 171 may be positioned on an insulating substrate 110 made of transparent glass or plastic. Pixel units may be defined by the gate lines and the data lines on the insulating substrate 110.

The gate lines 121 may transfer a gate signal and may extend mainly in a substantially horizontal direction. Each gate line 121 may include gate electrodes 124 protruding from the gate line 121 and a gate pad 129 that is a wide end portion for connection with another layer or a gate driver (not illustrated).

The gate electrode 124 may be formed of the same low-resistance metal pattern as the gate line. Although only the case in which the gate electrode 124 is formed of a single layer illustrated in an exemplary embodiment, the gate electrode may be formed of a double layer.

As an example, in the case in which the gate electrode 124 is formed of a double layer, the gate electrode 124 may have a structure in which a lower metal layer made of any one selected from aluminum (Al) and aluminum neodymium (AlNd) and an upper metal layer made of molybdenum (Mo) are sequentially stacked.

The lower metal layer may be a layer serving as a path of an electric signal corresponding to an original function of a wire. The lower metal layer may be formed of aluminum (Al) or aluminum neodymium (AlNd) having low resistivity.

The upper metal layer may be a layer for protecting the lower metal layer and may serve to prevent hillocking of aluminum (Al) generated in a high temperature subsequent process and to lower contact resistance between a pixel electrode and the lower metal layer.

Next, a gate insulating layer 140 made of an insulating material (i.e., silicon nitride and/or silicon oxide) is disposed on the gate line 121. Although FIG. 2 illustrates a gate insulating layer 140 having a single layer structure according to an exemplary embodiment, the gate insulating layer 140 is not limited to a single layer. In an exemplary embodiment, the gate insulating layer 140 may have a double layer structure or triple layer structure.

Next, semiconductor layers 154 made of an oxide semiconductor may be formed on the gate insulating layer 140. The semiconductor layer 154 may extend mainly in a vertical direction and may include projections protruding toward the gate electrode 124.

The semiconductor layer 154 contains at least one of zinc (Zn), indium (In), tin (Sn), gallium (Ga), and hafnium (Hf). In detail, an exemplary embodiment includes the semiconductor layer 154 made of indium (In)-gallium (Ga)-zinc (Zn) oxide (IGZO). In more detail, the semiconductor layer 154 may include an n-type oxide semiconductor. The n-type oxide semiconductor may include any one selected from the group consisting of ZnO, ZnGaO, ZnInO, In₂O₃, InGaZnO, and ZnSnO.

The semiconductor layer 154 according to an exemplary embodiment includes a copper doped oxide semiconductor. More specifically, metals forming the n-type oxide semiconductor (i.e., zinc (Zn), indium (In), tin (Sn), gallium (Ga), and hafnium (Hf)) and copper may be substituted with each other, thereby forming the semiconductor layer 154 in a form of copper monoxide or copper dioxide.

A content of copper doped on the semiconductor layer 154 is 0.2% to 0.82%. In detail, a content of copper diffused to the semiconductor layer 154 with respect to the entire content of the oxide semiconductor material is 0.2% to 0.82%.

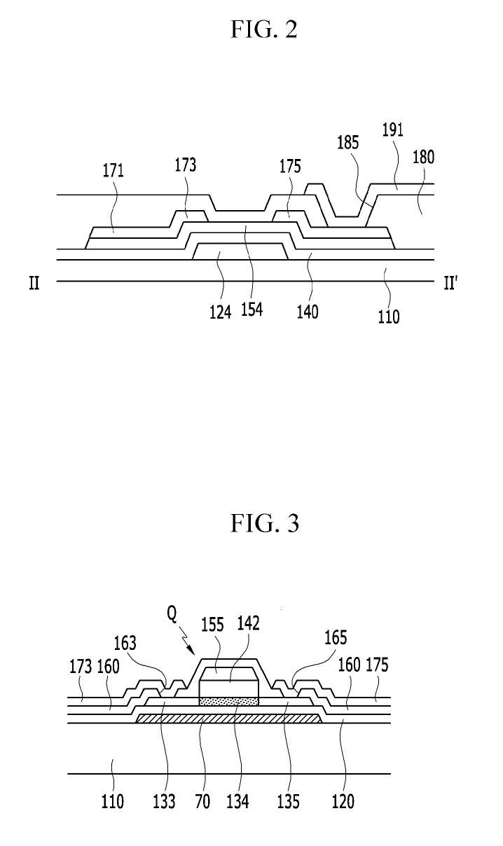

Although only a thin film transistor having a bottom gate structure is illustrated in FIG. 2, exemplary embodiments are not limited to a thin film transistor having a bottom gate structure. An exemplary embodiment may include a thin film transistor having any structure including a top gate structure as illustrated in FIG. 3.

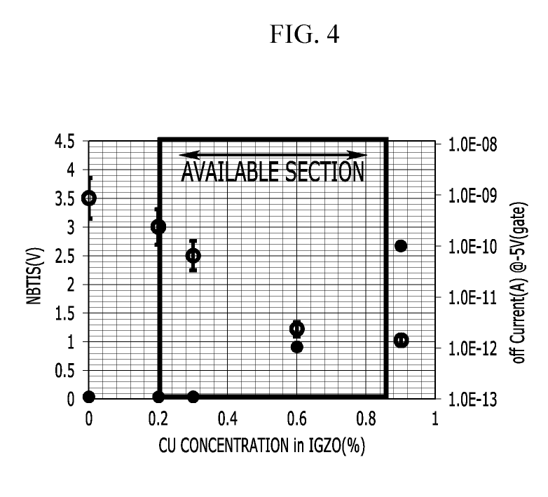

A thin film transistor array panel having the top gate structure will be described below with reference to FIG. 3. FIG. 4 is a graph illustrating negative bias under thermal and illumination stress (NBTIS) characteristics of an element depending on a concentration of copper diffused to a semiconductor layer 154 made of IGZO. Here, the NBTIS characteristics indicate when light is irradiated on a thin film transistor at an angle of 60 degrees using a light source such as backlight. This is to test electro-optical reliability in consideration that when the thin film transistor according to an exemplary embodiment is used as a driving element of a display device. In the case of a liquid crystal display device including backlight as a light source for image formation, light from the backlight may be incident on a channel layer to degrade performance.

Referring to FIG. 4, it was confirmed that in an exemplary embodiment in the case in which the content of the oxide diffused to the semiconductor layer was less than 0.2%, NBTIS of the element was high, such that the thin film transistor was degraded. In the case in which the content of copper was more than 0.82%, a leakage current (off current) value was increased.

The data lines 171, source electrodes 173, and drain electrodes 175 connected to the data line 171 may be formed on the semiconductor layer 154 and the gate insulating layer 140.

The data line 171 may transfer data signals and may mainly extend in the vertical direction to thereby cross the gate line 121. The source electrode 173 may extend from the data line 171 to be overlapped with the gate electrode 124 and may have a substantial U shape.

The drain electrode 175 may be separated from the data line 171 and may have the U shape of the source electrode 173. However, an exemplary embodiment includes the drain electrode 175 having various modified shapes.

The data line 171, the source electrode 173, and drain electrode 175 may include copper (Cu) or a copper alloy. According to an exemplary embodiment, the copper alloy forming the data line 171, the source electrode 173, and the drain electrode 175 may contain copper (Cu) and may further contain at least one element selected from Mn, Mg, Ca, Ni, Zn, Si, Al, Be, Ga, In, Fe, Ti, V, Co, Zr, Hf, and Ce.

The data line 171, the source electrode 173, and the drain electrode 175 may have tapered side surfaces.

Portions that are not covered by the data line 171 and the drain electrode 175 in addition to portions between the source electrode 173 and the drain electrode 175 may be present in the projection of the semiconductor layer 154. The semiconductor layer 154, except for exposed portions of the projection, may be disposed substantially on the same plane as the data line 171 and the drain electrode 175.

A single gate electrode 124, a single source electrode 173, and a single drain electrode 175 form a single thin film transistor (TFT) together with the projection of the semiconductor layer 154, and a channel of the thin film transistor may be disposed in the projection between the source electrode 173 and the drain electrode 175.

A passivation layer 180 may be positioned on the data line 171, the drain electrode 175, and the exposed portion of the projection of the semiconductor layer 154. The passivation layer 180 may include at least one of an inorganic insulating material (i.e., silicon nitride and/or silicon oxide), an organic insulating material, and a low k insulating material. Although not illustrated in FIG. 2, in an exemplary embodiment, the passivation layer 180 may have a multilayer structure including a first passivation layer made of silicon oxide and a second passivation layer made of silicon nitride.

A pixel electrode 191 and a contact assistant member may be positioned on the passivation layer 180. The pixel electrode 191 and the contact assistant member may include a transparent conductive material (i.e., indium tin oxide (ITO) and/or indium zinc oxide (IZO)) or a reflective metal (i.e., aluminum, silver, chromium, and/or an alloy of aluminum, silver, and/or chromium).

The pixel electrode 191 may be physically and electrically connected to the drain electrode 175 through a contact hole 185 and may be applied with a data voltage from the drain electrode 175.

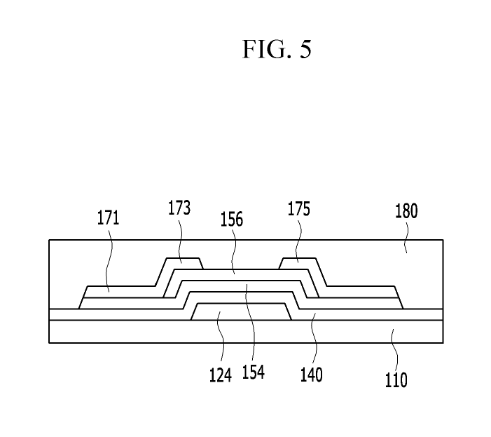

FIG. 5 is a cross-sectional view of a thin film transistor array panel according to an exemplary embodiment. A description of the same components as those described in FIGS. 1 and 2 will be omitted for brevity.

Referring to FIG. 5, an etch stopper 156 may be formed in a thin film transistor according to an exemplary embodiment.

The etch stopper 156 may cover the channel of the semiconductor layer 154 to prevent the channel of the thin film transistor from being damaged or deformed by etching (i.e., etching from gas and/or a solution) in a subsequent process. For example, an etching process of the source electrode 173 and the drain electrode 175 may otherwise damage or deform the channel of the semiconductor layer 154 without the etch stopper 156. In addition, the etch stopper 156 may block impurities (i.e., hydrogen) from being diffused from the insulating layer (i.e., the passivation layer 180 positioned on the semiconductor layer 154) to the semiconductor layer 154.

Referring to FIG. 3, a light blocking layer 70 may be positioned on an insulating substrate 110 including glass and/or plastic. The light blocking layer 70 may block light from reaching an oxide semiconductor to be stacked later, thereby making it possible to block the oxide semiconductor from losing characteristics as the semiconductor. Therefore, it is preferable that the light blocking layer 70 may include a material that does not transmit light in a wavelength band to be blocked so that the light does not reach the oxide semiconductor. The light blocking layer 70 may include an organic insulating material, inorganic insulating material, a conductive material such as a metal), and may be formed of a single layer film or multilayer film.

However, the light blocking layer 70 may be omitted according to conditions. More specifically, in the case in which light is not irradiated at a lower portion of the insulating substrate 110 (i.e., in the case in which the thin film transistor according to an exemplary embodiment of the present invention is used to an organic light emitting diode display device), the light blocking layer 70 may be omitted.

A buffer layer 120 may be positioned on the light blocking layer 70. The buffer layer 120 may include an insulating oxide (i.e., silicon oxide (SiOₓ), aluminum oxide (Al₂O₃), hafnium oxide (HfO₃), or yttrium oxide (Y₂O₃)). The buffer layer 120 may block impurities from being introduced from the insulating substrate 110 to a semiconductor to be stacked later, thereby making it possible to protect the semiconductor and improve interfacial characteristics of the semiconductor. A thick of the buffer layer 120 may be 500 nm to 1 μm. However, exemplary embodiments may also include a buffer layer of any thickness.

A semiconductor layer 134, a source electrode 133, a drain electrode 135 may be positioned on the buffer layer 120.

The semiconductor layer 134 may include at least one of zinc (Zn), indium (In), tin (Sn), gallium (Ga), and hafnium (Hf). In detail, in the an exemplary embodiment may include the semiconductor layer 134 including indium (In)-gallium (Ga)-zinc (Zn) oxide (IGZO). In more detail, the semiconductor layer 134 may include an n-type oxide semiconductor. The n-type oxide semiconductor may include any one selected from the group consisting of ZnO, ZnGaO, ZnInO, In₂O₃, InGaZnO, and ZnSnO.

The semiconductor layer 134 according to an exemplary embodiment includes a copper doped oxide semiconductor. More specifically, metals forming the n-type oxide semiconductor (i.e., zinc (Zn), indium (In), tin (Sn), gallium (Ga), and hafnium (Hf)) and copper may be substituted with each other, thereby forming the semiconductor layer 134 in a form of copper monoxide or copper dioxide.

A content of copper doped on the semiconductor layer 134 may be 0.2% to 0.82%. In detail, a content of copper diffused to the semiconductor layer 134 with respect to the entire content of the oxide semiconductor material may be 0.2% to 0.82%.

In the case in which the light blocking layer 70 is present, the semiconductor layer 134 may be shielded by the light blocking layer 70.

Referring to FIGS. 2 and 3 as described above, the source electrode 133 and the drain electrode 135 may be separated from each other and positioned at both sides of the semiconductor layer 134 while also being connected to the semiconductor layer 134.

The source electrode 133 and drain electrode 135 may include copper (Cu) or a copper alloy. In detail, the copper alloy forming the source electrode 133 and the drain electrode 135 may include copper (Cu) and further include at least one element selected from Mn, Mg, Ca, Ni, Zn, Si, Al, Be, Ga, In, Fe, Ti, V, Co, Zr, Hf, and Ce.

An insulating layer 142 may be positioned on the semiconductor layer 134. The insulating layer 142 may cover the semiconductor layer 134. In addition, the insulating layer 142 may not be substantially overlapped with the source electrode 133 or the drain electrode 135.

The insulating layer 142 may be a single layer or a multilayer having at least two layers.

A gate electrode 155 may be positioned on the insulating layer 142. An edge boundary of the gate electrode 155 and an edge boundary of the insulating layer 142 may substantially coincide with each other to thereby be aligned.

The gate electrode 155 may include a portion overlapped with the semiconductor layer 134. In other words (i.e., the semiconductor layer 134 may be covered by the gate electrode 155. The source electrode 133 and the drain electrode 135 may be positioned at both sides of the semiconductor layer 134. The source electrode 133 and the drain electrode 135 may not be substantially overlapped with the gate electrode 155. Therefore, parasitic capacitance between the gate electrode 155 and the source electrode 133 or parasitic capacitance between the gate electrode 155 and the drain electrode 135 may be decreased.

The gate electrode 155 may include a metal (i.e., aluminum (Al), silver (Ag), copper (Cu), molybdenum (Mo), chromium (Cr), tantalum (Ta), titanium (Ti), and/or an alloy of aluminum (Al), silver (Ag), copper (Cu), molybdenum (Mo), chromium (Cr), tantalum (Ta), and/or titanium (Ti)). The gate electrode 155 may have a single layer structure or multilayer structure. An example of the multilayer may include a double layer including a lower layer made of titanium (Ti), tantalum (Ta), molybdenum (Mo), and/or ITO and an upper layer made of copper (Cu), a triple layer including molybdenum(Mo)-aluminum(Al)-molybdenum(Mo). However, the gate electrode 155 may include various metals or conductors except for the above-mentioned materials.

According to an exemplary embodiment, a boundary between the semiconductor layer 134 and the source electrode 133 or a boundary between the semiconductor layer 134 and the drain electrode 135 may be substantially aligned to thereby coincide with the edge boundaries of the gate electrode 155 and the insulating layer 142. However, the boundary between the semiconductor layer 134 and the source electrode 133 or the drain electrode 135 may be positioned slightly inwardly of the edge boundaries of the gate electrode 155 and the insulating layer 142.

The gate electrode 155, the source electrode 133, and the drain electrode 135 may form a thin film transistor (TFT) Q together with the semiconductor layer 134, and a channel of the thin film transistor may be formed on the semiconductor layer 134.

A passivation layer 160 may be positioned on the gate electrode 155, the source electrode 133, the drain electrode 135, and the buffer layer 120. The passivation layer 160 may include at least one of an inorganic insulating material (i.e., silicon nitride and/or silicon oxide) and an organic insulating material. The passivation layer 160 may contain a contact hole 163 exposing the source electrode 133 and a contact hole 165 exposing the drain electrode 135.

A data input electrode 173 and a data output electrode 175 may be positioned on the passivation layer 160. The data input electrode 173 may be electrically connected to the source electrode 133 of the thin film transistor Q through the contact hole 163 of the passivation layer 160, and the data output electrode 175 may be electrically connected to the drain electrode 135 of the thin film transistor Q through the contact hole 165 of the passivation layer 160.

Alternatively, a color filter (not illustrated) or an organic film (not illustrated) including an organic material may be further positioned on the passivation layer 160, and the data input electrode 173 and the data output electrode 175 may be positioned on the color filter or the organic film.

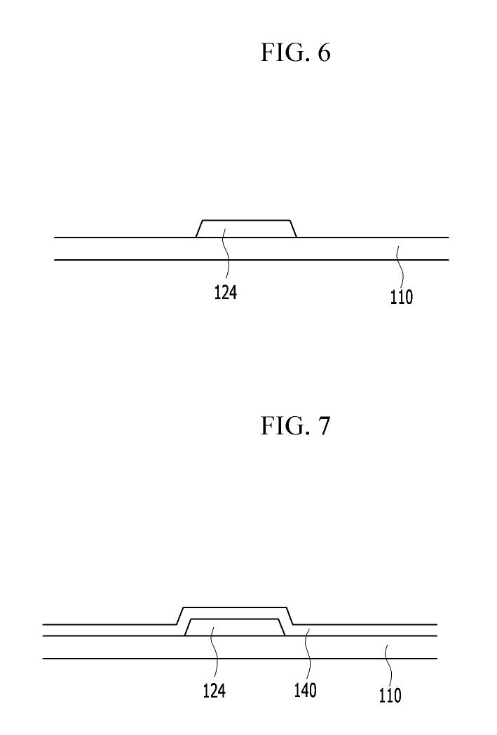

FIGS. 6, 7, 8, 9, and 10 are views for describing a method for manufacturing a thin film transistor array panel illustrated in FIG. 2. A detailed description of the same components as the above-mentioned components will be omitted for brevity.

Referring to FIG. 6, a low-resistance metal layer is stacked on an insulating substrate 110 and a gate line 121 including a gate electrode 124 is formed through a photolithography.

The gate electrode 124 may include the same metal layer as the gate line. Although only the case in which the gate electrode 124 is formed of a single layer is illustrated in an exemplary embodiment of the present invention, the gate electrode may be formed of a double layer.

As an example, in the case in which the gate electrode 124 is formed of a double layer, the gate electrode 124 may have a structure in which a lower metal layer including at least one of aluminum (Al) and aluminum neodymium (AlNd) and an upper metal layer including molybdenum (Mo) are sequentially stacked.

The lower metal layer may be a layer serving as a path of an electric signal, corresponding to an original function of a wire may include copper (Cu), aluminum (Al), and/or aluminum neodymium (AlNd) having low resistivity.

The upper metal layer may be a layer for protecting the lower metal layer and may serve to prevent aluminum (Al) hillock generated in a high temperature subsequent process and may lower contact resistance between a pixel electrode and the lower metal layer.

Next, referring to FIG. 7, a gate insulating layer 140 may be formed on the gate line 121 by a chemical vapor deposition (CVD) method. In this case, silicon tetrafluoride (SiF₄) gas may be supplied into a CVD chamber to form the gate insulating layer 140 is formed. Additionally, at least one of silane (SiH₄) gas, hydrogen (H₂) gas, and nitrogen gas (NH₃) may be to the silicon tetrafluoride gas.

Although the gate insulating layer having a single layer is illustrated and described in an exemplary embodiment, exemplary embodiments of this application are not so limited. A gate insulating layer having a double layer or triple layer may be formed.

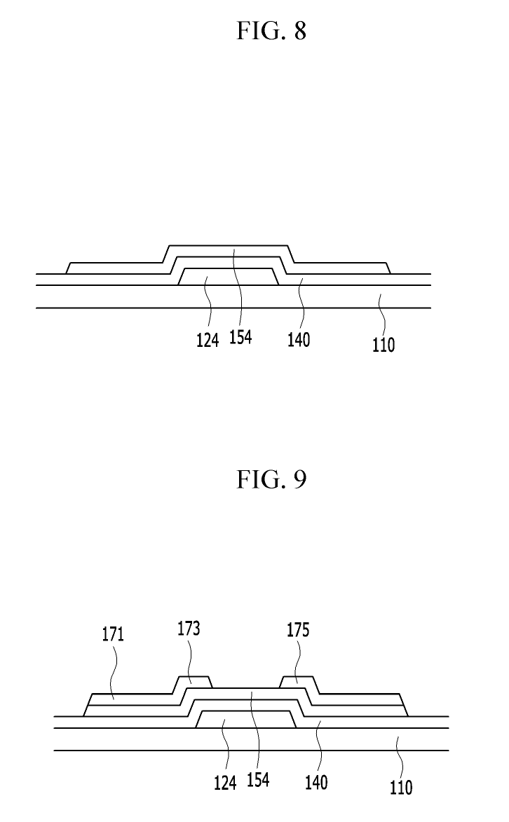

Referring to FIG. 8, after the gate insulating layer 140 is formed; a semiconductor layer 154 may be formed in the CVD chamber. The semiconductor layer 154 may include at least one of zinc (Zn), indium (In), tin (Sn), gallium (Ga), and hafnium (Hf). In detail, the semiconductor layer 154 may include indium (In)-gallium (Ga)-zinc (Zn) oxide (IGZO). In more detail, the semiconductor layer 154 may also include an n-type oxide semiconductor. The n-type oxide semiconductor may include at least one of ZnO, ZnGaO, ZnInO, In₂O₃, InGaZnO, and ZnSnO.

The semiconductor layer 154 may extend mainly in a vertical direction and may include projections protruding toward the gate electrode 124.

Referring to FIG. 9, after the semiconductor layer 154 is formed; a data line 171 including a data line, a source electrode 173, and a drain electrode 175 may be formed through photolithography. The drain electrode 175 may be spaced apart from the source electrode 173 and may be positioned on a portion opposite to the source electrode 173 based on the gate electrode 124.

The data line 171 may transfer data signals and may mainly extend in the vertical direction to thereby cross the gate line 121. The source electrode 173 may extend toward the gate electrode 124 to thereby have a U shape. However, the source electrode may have various modified shapes.

The drain electrode 175 may be separated from the data line 171 and may extend upward from the middle of the U-shaped source electrode 173.

The data line 171, the source electrode 173, and drain electrode 175 may include copper (Cu) or a copper alloy. The copper alloy may include copper (Cu) and further include at least one element selected from Mn, Mg, Ca, Ni, Zn, Si, Al, Be, Ga, In, Fe, Ti, V, Co, Zr, Hf, and Ce.

Unlike the exemplary embodiment described in FIG. 9, the semiconductor layer 154, the source electrode 173, and the drain electrode 175 may be formed using a single mask.

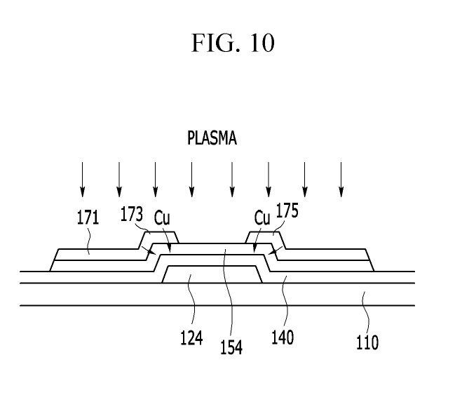

Referring to FIG. 10, diffusion of copper to the semiconductor layer 154 through side walls of the source electrode 173 and the drain electrode 175 may be induced by heat treatment and plasma treatment.

The heat treatment may be performed at about 100° C. or more, and the plasma treatment may be performed using any one of nitrogen (N₂), oxygen (O₂), and nitrous oxide (N₂O) or simultaneously using nitrogen (N₂) and oxygen (O₂).

In the case of inducing diffusion of copper by simultaneously performing heat treatment and plasma treatment, a content of copper doped on the oxide semiconductor layer is 2 times to 6 times higher than the content of copper doped on the oxide semiconductor layer in the case of performing only heat treatment.

The semiconductor layer 154 includes copper oxide due to copper doping by heat treatment and plasma treatment. In detail, metals forming the n-type oxide semiconductor (i.e., zinc (Zn), indium (In), tin (Sn), gallium (Ga), and/or hafnium (Hf)) may be substituted with copper, thereby forming the oxide semiconductor layer in a form of copper monoxide or copper dioxide.

The content of copper doped on the semiconductor layer 154 by heat treatment and plasma treatment may be 0.2% to 0.82%. As described above, in the case of the semiconductor layer containing a suitable content of copper oxide, reliability of the element may be improved. However, in the case in which the content is out of a suitable content range, a leakage current may be increased such that the thin film transistor array panel may not operate as a panel.

Unlike an oxide semiconductor according to the related art in which copper is directly added to the oxide semiconductor, in the case of the oxide semiconductor according to an exemplary embodiment, a concentration of an electron in the oxide semiconductor layer may be decreased by indirectly inducing diffusion of copper to the semiconductor layer through the wiring containing copper.

In other words, copper is formed as copper monoxide and copper dioxide in the oxide semiconductor layer 154 by plasma treatment, and copper monoxide and copper dioxide each contribute to stabilizing reliability of the element and improving lifetime characteristics of the element through electron absorption in the oxide semiconductor layer 154.

In the thin film transistor array panel including the etch stopper 156 illustrated in FIG. 4, copper may be diffused to the semiconductor layer 154 by heat treatment at 100° C. or more.

After a passivation layer 180 is formed so as to cover the semiconductor layer 154, a contact hole 185 exposing a portion of the drain electrode 175 may be formed by photolithography. In the case of depositing a transparent conductive layer (not illustrated) on the passivation layer 180 and forming a pixel electrode 191 electrically connected to the drain electrode by photolithography, the thin film transistor array panel according to an exemplary embodiment illustrated in FIG. 2 may be formed.

The passivation layer 180 may include an inorganic insulating material (i.e., silicon nitride and/or silicon oxide), an organic insulating material, and/or a low k insulating material. Although not illustrated in FIG. 2, in an exemplary embodiment, the passivation layer 180 includes a multilayer structure including a first passivation layer made of silicon oxide and a second passivation layer including silicon nitride.

The contact holes 185 exposing one end of the drain electrodes 175 may be positioned in the passivation layer 180.

The pixel electrode 191 may be positioned on the passivation layer 180. The pixel electrode 191 may be made of a transparent conductive material (i.e., ITO and/or IZO) and/or a reflective metal (i.e., aluminum, silver, chromium, an alloy of aluminum, silver, and/or chromium).

The pixel electrode 191 may be physically and electrically connected to the drain electrode 175 through a contact hole 185 and may be applied with a data voltage from the drain electrode 175.

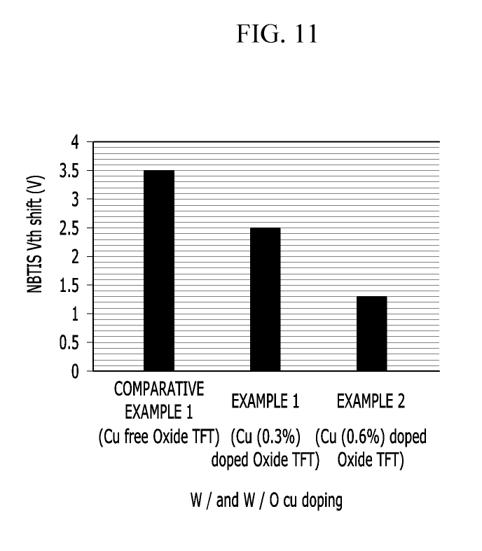

FIG. 11 is a graph illustrating NBTIS shift values depending on a copper content in the semiconductor layer of the thin film transistor according to an exemplary embodiment.

Referring to the graph of FIG. 11, in the case of Examples 1 and 2 where copper (Cu) is doped on a semiconductor layer as a channel layer, a change in a threshold voltage is smaller than in Comparative Example in which copper is not doped. More specifically, FIG. 11 illustrates results obtained by measuring a change in the amount of the threshold voltage of a transistor by NBTIS while changing a content ratio of copper (Cu) in a semiconductor layer (IGZO layer). The content ratio of the doped copper means a ratio of copper to a total content of copper (Cu).

After applying predetermined NBTIS to transistors having a channel layer with a content ratio of copper of 0%, 0.3%, and 0.6%, a change degree of the threshold voltage V of each transistor was measured. Referring to FIG. 11, it may be appreciated that in the case of using an oxide semiconductor layer that was not doped with copper corresponding to Comparative Example 1, changes in characteristics (i.e., a change in the threshold voltage) of the transistor by NBTIS were larger than those in Examples 1 and 2 where copper was doped.

Examples 1 and 2 correspond to the cases in which the IGZO oxide semiconductor layer was doped with 0.3% copper and 0.6% copper, respectively, and it was shown that the change in the characteristics of the transistor by NBTIS in Example 2 was smaller than that in Example 1.

In other words, it may be appreciated from the graphs of FIGS. 4 and 11 that excellent mobility may be maintained and electric and optical reliability may be improved by doping copper on the oxide semiconductor and suitably adjusting the concentration of copper.

According to the exemplary embodiments, in the thin film transistor array panel, a lifetime of a thin film transistor element may be increased and reliability thereof may be improved due to a decrease in an electron concentration in the oxide semiconductor layer.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. A thin film transistor array panel, comprising:
a gate line disposed on a substrate, the gate line comprising a gate electrode;
a gate insulating layer disposed on the gate electrode;
a semiconductor layer disposed on the substrate, the semiconductor layer comprising an oxide semiconductor;
a data line disposed on the substrate and crossing the gate line;
a data line layer comprising a source electrode connected to the data line and a drain electrode facing the source electrode; and
a passivation layer covering the source electrode and the drain electrode,
wherein the data line layer comprises copper or a copper alloy, and the semiconductor layer comprises a copper doped oxide semiconductor, and
a content of copper doped on the oxide semiconductor is 0.2% to 0.82%.

2. The thin film transistor array panel of claim 1, wherein:
the copper doped on the oxide semiconductor layer is diffused to the oxide semiconductor layer by heat treatment and plasma treatment of the source electrode and the drain electrode.

3. The thin film transistor array panel of claim 2, wherein:
the copper doped oxide semiconductor layer comprises at least one of copper monoxide and copper dioxide.

4. The thin film transistor array panel of claim 3, wherein:
the oxide semiconductor is an n-type oxide semiconductor.

5. The thin film transistor array panel of claim 4, wherein:
the n-type oxide semiconductor comprises at least one of ZnO, ZnGaO, ZnInO, In₂O₃, InGaZnO, and ZnSnO.

6. The thin film transistor array panel of claim 2, further comprising:
an etch stopper disposed between the source electrode and the drain electrode and the semiconductor layer.

7. The thin film transistor array panel of claim 1, further comprising:
an insulating layer disposed between the gate electrode and the semiconductor layer, wherein the gate line comprising the gate electrode is disposed on the semiconductor layer.

8. A method for manufacturing a thin film transistor array panel, the method comprising:
disposing a gate line comprising a gate electrode on a substrate;
disposing a gate insulating layer on the gate line;
disposing a semiconductor layer comprising an oxide semiconductor on the gate insulating layer;
disposing a data line layer comprising a source electrode and a drain electrode on the semiconductor layer;
treating surfaces of the source electrode and the drain electrode to diffuse copper to the semiconductor layer with heat and plasma; and
disposing a passivation layer on the substrate to cover the source electrode, the drain electrode, and the semiconductor layer;
wherein the data line layer comprises copper or a copper alloy, and the semiconductor layer comprises a copper doped oxide semiconductor, and
a content of copper doped on the oxide semiconductor is 0.2% to 0.82%.

9. The method of claim 8, wherein:
the treating the surfaces of the source electrode and the drain electrode with plasma is performed using at least one of nitrogen (N₂), oxygen (O₂), and nitrous oxide (N₂O).

10. The method of claim 9, wherein:
the treating the surfaces of the source electrode and the drain electrode with plasma are performed by simultaneously using nitrogen (N₂) and oxygen (O₂).

11. The method of claim 9, wherein the copper doped oxide semiconductor layer comprises at least one of copper monoxide and copper dioxide.

12. The method of claim 11, wherein the oxide semiconductor is an n-type oxide semiconductor.

13. The method of claim 12, wherein the n-type oxide semiconductor comprises at least one of ZnO, ZnGaO, ZnInO, In₂O₃, InGaZnO, and ZnSnO.

14. A method for manufacturing a thin film transistor array panel, comprising:
disposing a gate line including a gate electrode on a substrate;
disposing a gate insulating layer on the gate line;
disposing a semiconductor layer comprising an oxide semiconductor on the gate insulating layer;
disposing an etch stopper on the semiconductor layer;
disposing a data line layer including a source electrode and a drain electrode on the semiconductor layer so that a portion of the etch stopper is exposed;
heat treating surfaces of the source electrode and the drain electrode to diffuse copper to the semiconductor layer; and
disposing a passivation layer on the substrate to cover the source electrode, the drain electrode, and the etch stopper,
wherein the data line layer comprises copper or a copper alloy, and the semiconductor layer comprises a copper doped oxide semiconductor, and
a content of copper doped on the oxide semiconductor is 0.2% to 0.82%.
